(19) United States
(12) Patent Application Publication
(10) Pub. No.: US 2009/0011375 A1
(43) Pub. Date: Jan. 8, 2009

(54) IMMERSION LIQUID FOR LIQUID IMMERSION LITHOGRAPHY PROCESS AND METHOD FOR FORMING RESIST PATTERN USING THE SAME

(76) Inventors: Taku Hirayama, Kanagawa (JP); Kazumasa Wakiya, Kanagawa (JP); Kotaro Endo, Kanagawa (JP); Masaaki Yoshida, Kanagawa (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/597,124

(22) PCT Filed: May 24, 2005
(86) PCT No.: PCT/JP2005/009477

§ 371 Date: Jun. 21, 2007

(30) Foreign Application Priority Data
May 25, 2004 (JP) 2004-155274

(51) Int. Cl. G03F 7/20; G03C 5/00

(52) U.S. Cl. 430/325; 430/449

(57) ABSTRACT

A liquid immersion lithography process is provided. In particular, the liquid immersion lithography process is one in which the resolution of a resist pattern is improved by exposure to light through a liquid having a refractive index higher than that of air and a predetermined thickness, while being arranged on at least a resist film in a pathway allowing exposure light for lithography to reach to the resist film. Accordingly, both the resist film and the liquid used are prevented from deterioration in liquid immersion lithography. Thus, the formation of a high-resolution resist pattern can be attained with liquid immersion lithography. Therefore, the liquid comprised of a silicon-based liquid transparent to exposure light used in the lithography process is employed as an immersion liquid for liquid immersion lithography.

### TECHNICAL FIELD

The present invention relates to a liquid which can be suitably used in a liquid lithography process by which the resolution of a resist pattern on at least a resist film on a route of allowing lithographic exposure light to reach to the resist film by exposing the above resist film, while being intervened by a liquid having a predetermined thickness and refractive index higher than air, and to a method for forming a resist pattern using such an immersion liquid.

### BACKGROUND ART

Lithography methods have been frequently used for the production of fine structures in various kinds of electronic devices, such as semiconductor devices and liquid crystal devices. However, as the device structures are miniaturized, resist patterns in lithography processes are also desired to be miniaturized.

In the advanced field, for example, a lithography process now allows the formation of a fine resist pattern having a line width of about 90 nm. However, finer pattern formation will be required in future.

For attaining the formation of such a fine pattern having a line width of less than 90 nm, a first point is to develop an aligner and a resist corresponding thereto. Common factors to consider for developing the aligner include shortening of wavelengths of optical sources such as F2 laser, EUV (extreme UV light), electron beam, and X-ray and increases in numerical aperture (NA) of lens.

However, the shortening of optical wavelength may require a new expensive aligner. In addition, even the resolution increases, a disadvantage of lowering a focal depth width occurs at high NA due to a trade-off relationship between the resolution and the focal depth width.

Recently, as a lithography technology for allowing such problems to be solved, a method known as a liquid immersion lithography process has been reported (e.g., Non-Patent Documents 1, 2, and 3). In this process, a liquid such as pure water or a fluorine-based inert liquid (immersion liquid) lies in predetermined thickness on at least a resist film between a lens and the resist film. In this method, the space of an exposure light path conventionally filled with inert gas such as air or nitrogen is replaced with a liquid having a larger refractive index (n), for example pure water to attain high resolution without a decrease in focal depth width in a manner similar to the use of a light source of shorter wavelength or a high NA lens even if the optical source having the same exposure wavelength is employed.

Such liquid immersion lithography has been remarkably noticed because the use thereof allows a lens implemented in the existing device to realize the formation of a resist pattern excellent in higher resolution property as well as excellent in focal depth in low costs.

[Non Patent Document 1] Journal of Vacuum Science & Technology B (J. Vac. Sci. Technol. B) (Issued country: U.S.A.), vol. 17, No. 6, pages 3306-3309, 1999.

[Non Patent Document 2] Journal of Vacuum Science & Technology B (J. Vac. Sci. Technol. B) (Issued country: U.S.A.), vol. 19, No. 6, pages 2353-2356, 2001.

[Non Patent Document 3] Proceedings of SPIE (Issued country: U.S.A.), Vol. 4691, pages 459-465, 2002.

### DISCLOSURE OF THE INVENTION

In the liquid immersion lithography process as described above, inert water, such as pure water and deionized water, and a fluorine-based inert liquid, such as a perfluoroether compound have been proposed as immersion liquids to be used, and inert water has been desired in terms of cost effectiveness and easiness of handling. As described above, the liquid immersion lithography process is premised on the use of a liquid having a higher refractive index (n) than inert gas, such as air or nitrogen. For example, the refractive index of the conventional immersion liquid is 1.33 for water and about 1.28 to 1.3 for a fluorine-based inert solution (measured using an Abbe refractometer NAR-1T, manufactured by ATAGO, Co., Ltd., at a visual light wavelength at room temperature).

The relationship between a refractive index and a pattern resolution in the liquid immersion lithography process can be represented by the following formula:

NA=n sin θ

$$Resolution = k 1 λ / NA = k 1 λ / ( n sin θ ) \\ = k 1 ( λ / n ) / sin θ$$

NA□ Convergent angle,
k1: Constant, λ: Wavelength, n: Refractive index

Accordingly, the higher the refractive index increases, the more the resolution property is improved in the liquid immersion lithography process. However, inert water and fluorine-based inert liquids, which have been conventionally used as an immersion liquid, may have a limited value of refractive index, so that the development of a novel immersion liquid having a higher refractive index has been desired. However, it is necessary for the immersion liquid to satisfy various kinds of conditions, such as transparency to exposure light and compatibility to a resist composition, thus the development thereof is not easy.

The resist composition, which has been commonly used in the art, is a composition established by widely investigating any of the potential resins in terms of the most essential characteristics, such as having transparency to exposure light. Such a resist composition is a composition superior in various resist characteristics including: transparency to exposure light, rectangularity of patterns, developing ability, and preservation stability, which has been established by expending many development resources. Therefore, for developing a new immersion liquid, an important factor is whether a presently-proposed resist composition can be directly applied in a liquid immersion lithography process or whether it requires few modifications.

The adequacy of a resist film to liquid immersion lithography can be evaluated on the basis of the following assay.

In other words, for evaluating the abilities of liquid immersion lithography to form resist patterns, it is considered sufficient to confirm the following three items: (i) the capabilities of an optical system based on the liquid immersion lithography process; (ii) influences of a resist film on an immersion liquid, and (iii) denaturation of the resist film by the immersion liquid.

In principle, as long as no light propagation loss, such as light reflection on the surface of water and the boundary of water with the surface of a photographic plate occurs, no problem occurs with respect to the above item (i). It is evident from assuming, for example, cases in which the photographic plate having a water-proof surface is immersed into water and the surface is then exposed to patterning light. In this case, the light propagation loss can be easily settled by adequately defining an incident angle of exposure light. Therefore, regardless of a resist film, a photographic plate, or an image formation screen, which is provided as an exposure target, no variation may occur in optical properties as long as each of them is inactive to an immersion liquid, or as long as those are prevented from any influence from the immersion liquid and exerting no influence on the immersion liquid. Therefore, the present item does not require any additional conformation experiment.

With respect to item (ii), the immersion liquid influences the resist film, specifically by allowing the components of the resist film to escape into the liquid, to change the refractive index of the immersion liquid. A change in the refractive index of the immersion liquid may lead to a change in the optical resolution properties of the pattern exposure. This is true based on theory without any experimentation. Thus, the present item can be sufficiently confirmed from the fact that the components of the immersion liquid escape into the immersion liquid, the composition of the immersion liquid is changed, or the refractive index is changed when it is immersed therein. Therefore, it is not necessary to confirm the resolution by actually carrying out irradiation of patterning light and development.

Conversely, when the resist film in the immersed liquid is exposed to patterning light and then developed to confirm its resolution properties, the quality of the resolution may be confirmed. However, it is hardly defined as to whether the cause is related to any influence of deterioration in the quality of the immersion liquid on the resolution properties thereof, any influence on the deterioration in the quality of the resist material on the resolution properties thereof, or both.

With respect to the item (iii) where the resolution properties of the resist film is deteriorated by deterioration of the resist film in the immersion liquid, it is sufficient to carry out an evaluation test for “performing a process of showering the resist film with the immersion liquid after exposure and then carrying out development, followed by testing the resolution properties of the resulting resist patterns”. Besides, in this evaluation process, the immersion liquid is directly poured on the resist film, so that the conditions of liquid immersion may be more severe. With respect to such a fact, when the test of exposure in complete immersion is carried out, a cause of a change in resolution properties is hardly defined whether it is due to an influence of deterioration of the immersion liquid, an influence of deterioration of the resist film with the immersion liquid, or both influences.

The above phenomena (ii) and (iii) are one and the same, so that these phenomena can be figured out by confirming the degree of deterioration of the resist film with the immersion liquid.

Based on such an analysis, the suitability of the presently-proposed resist film to liquid immersion lithography as described above can be confirmed by an evaluation test of “performing a process of showering the resist film with the immersion liquid after exposure and then carrying out development, followed by testing the resolution properties of the resulting resist patterns” (hereinafter, referred to as “Evaluation Test 1”). Furthermore, it can be also confirmed by carrying out an evaluation test that simulates an actual production process with a “two-beam interference process” using interference light through a prism instead of exposure patterning light and placing a sample in liquid immersion, followed by developing an image (hereinafter, referred to as “Evaluation Test 2”). Furthermore, the relationship between the resist film and the immersion liquid can be confirmed by using a quartz-crystal oscillator method (a method for measuring a film thickness where the film thickness is detected on the basis of a change in weight by a quarts-crystal microbalance) as a method for measuring a trace level of a change in film thickness (hereinafter, referred to as “Evaluation Test 3”).

As described above, the production of a new resist film suitable for liquid immersion lithography requires many development resources. Thus, for developing a new immersion liquid, the adaptability of the presently proposed resist composition should be confirmed.

The present invention has been made in consideration of the abovementioned problem inherent to the prior art and intends to provide an immersion liquid having a high refractive index, which can be correspondingly applied to a resist film made of the conventional resist composition established by expending many development resources. Specifically, the present invention intends to provide an immersion liquid having a high refractive index, transparency to exposure light, and an ability of preventing a resist film from deterioration in liquid immersion lithography, thereby allowing the formation of a high-resolution resist pattern using liquid immersion lithography.

For solving the above problem, the characteristic feature of the liquid immersion liquid for liquid immersion lithography process, which can be suitably used in such a process, is to consist of a silicon-based liquid transparent to exposure light used in the liquid immersion lithography process.

In addition, the characteristic feature of the method for forming a resist pattern of the present invention is to include the steps of: forming at least a photoresist film on a substrate; directly arranging an immersion liquid containing a silicon-based liquid transparent to exposure light to be used in the exposure process; selectively exposing the resist film through both the immersion liquid and the protective film to light; optionally heating the resist film; and forming a resist pattern by developing the resist film.

Furthermore, the characteristic feature of the second method for forming a resist pattern of the present invention, which is a method for forming a resist pattern using a liquid immersion lithography process, is to include the steps of: forming at least a photoresist film on a substrate; forming a protective film on the resist film; directly arranging an immersion liquid containing a silicon-based liquid transparent to exposure light to be used in the exposure process; selectively exposing the resist film through both the immersion liquid and the protective film to light; optionally heating the resist film, optionally heating the resist film; and forming a resist pattern by developing the resist film.

In the above configuration, the liquid immersion lithography process may be preferably configured such that the resolution of a resist pattern can be improved by exposure while allowing a liquid having a predetermined thickness and a refractive index higher than that of air to be placed on at least the resist film in a pathway along which exposure light for lithography reaches to a resist film.

According to the present invention, a silicon-based liquid having a high refractive index is used. Therefore, even if an optical source having the same exposure wavelength are employed, high resolution properties can be attained in the same manner as those attained using a light source having a shorter wavelength or a high NA lens, and simultaneously a decrease in focal depth width can be prevented, thereby applying to the formation of finer patterns. In addition, even if the resist film is constructed using any resist composition commonly used in the art, the resulting resist pattern has a high accuracy and an excellent profile configuration of resist patterns and does not cause any improper phenomenon, for example, roughening of the surface of resist pattern such as T-top formation of the resist pattern, fluctuation of patterns, or stringing phenomenon. In addition, an excellent resist pattern can be formed even when a protective film is formed on a resist film and the immersion liquid of the present invention is then arranged on such a protective film.

Therefore, the resist pattern formation by a liquid immersion lithography process can be effectively carried out using the immersion liquid of the present invention.

### BRIEF DESCRIPTION OF THE DRAWINGS

FIG. 1 is a diagram that represents a variation in film thickness of the resist film per time period of immersion.

### PREFERRED MODE FOR CARRYING OUT THE INVENTION

The immersion liquid of the present invention comprises a silicon-based liquid used in liquid immersion lithography which is transparent to exposure light and hardly denatures and dissolves a resist film. The silicon-based liquid shows a high refractive index compared with that of a fluorine-based solution or water because of its molecular structure. Therefore, even if optical sources having the same exposure wavelength are employed, high resolution properties can be attained in the same manner as those attained using a light source having a shorter wavelength or a high NA lens, while simultaneously preventing a decrease in focal depth width, thereby applying to the formation of finer patterns.

A refractive index varies as a measurement wavelength and a measurement temperature affect thereon, so that it is hard to principally define the level of refractive index being desired for the silicon-based liquid of the present invention. However, when the refractive index is measured under the same exposure wavelength and temperature as those of a liquid immersion lithography process, a favorable refractive index is at least 0.01 or more, preferably 0.1 or more, more preferably 0.2 or more higher than the refractive index of water.

The refractive index level required for the silicon-based liquid of the present invention will now be represented. When it is measured with visible light at room temperature, it is 1.34 or more, more preferably 1.35 or more, further preferably 1.36 or more (measured using an Abbe refractometer NAR-1T, manufactured by ATAGO, Co., Ltd.). In addition, when it is measured at a wavelength of 156.2 nm at room temperature, it is 1.5 or more, more preferably 1.6 or more, further preferably 1.65 or more. In addition, when it is measured at a wavelength of 192.8 nm at room temperature, it is 1.4 or more, more preferably 1.5 or more, further preferably 1.55 or more. Furthermore, when it is measured at a wavelength of 246.8 nm at room temperature, it is 1.35 or more, more preferably 1.4 or more, further preferably 1.45 or more.

Concrete examples of the silicon-based liquid having such a refractive index include an organic siloxane. The organic siloxane is represented by the following general formula (1):

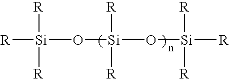

in which R is an organic group and n is an integer of 0 or more.

In the above general formula, an example of the organic group R may include hydrocarbon groups having 1 to 8 carbon atoms and halogenated hydrocarbon groups having 1 to 8 carbon atoms. Concrete examples of the organic R include a methyl group, an ethyl group, —CH₂CH₂CF₃. Among them, the methyl group is preferable.

In the above general formula, n is preferably in the range of 0 to 40, more preferably in the range of 0 to 10, further preferably in the range of 0 to 5, particularly preferably in the range of 0 to 2. Most preferably, n is zero (0).

Such a silicon-based liquid used may be a commercially available product, such as “SIH6115.0” (refractive index n=1.3774, boiling point 100° C., manufactured by Chisso Corporation), “SIO6703.0” (refractive index n=1.3848, boiling point 153° C., manufactured by Chisso Corporation), “SID2655.0) (refractive index n=1.3895, boiling point 195° C., manufactured by Chisso Corporation), “DMS-T35” (refractive index n=1.4035, manufactured by Chisso Corporation), “LS7130” (refractive index n=1.3774, boiling point 100° C., manufactured by Shin-Etsu Silicone Co., Ltd.), “KF-96-5000” (refractive index n=1.4035, manufactured by Shin-Etsu Silicone Co., Ltd.) (refractive index n is measured using an Abbe refractometer NAR-1T (manufactured by ATAGO, Co., Ltd.) at a visual light wavelength at room temperature).

In addition, the immersion liquid of the present invention is a silicon-based liquid having transparency to exposure light to be used in a liquid immersion lithography process. Here, the term “having transparency to exposure light” means having transparency at a level that does not affect the liquid immersion lithography process. Concretely, the value of an extinction coefficient k to exposure light is 0 to 0.1, preferably 0 to 0.05, more preferably 0 to 0.01, particularly preferably 0.

The immersion liquid of the present invention is suitable for a liquid immersion lithography process, for example, with an Excimer laser at wavelengths of 157 nm, 193 nm, and 247 nm, particularly preferably applied in a liquid immersion lithography process with an Excimer laser at a wavelength of 193 nm.

Resist films, which can be used in the present invention, may use any resist composition commonly used in the art as long as it does not denature or dissolve in a silicon-based liquid to be used as an immersion liquid.

The resist composition to be used in a liquid immersion lithography process of the present invention may be any resist composition for positive and negative photoresists. Examples of such compositions are as follows:

First, base polymers (resin components), which can be used in a positive photoresist composition, include an acrylic resin, a cycloolefin resin, a silsesquioxane resin, and a fluorine-containing polymer.

The acrylic resin described above has, for example, a structural unit (a1) derived from a (meth) acrylic ester having a acid dissociable, dissolution inhibiting group, and is preferably, for example, a resin containing a structural unit (a1) derived from the (meth) acrylic acid ester having the acid dissociable, dissolution inhibiting group, and also containing a structural unit derived from an additional (meth) acrylic acid ester other than the unit (a1), in which the structural unit derived from the (meth) acrylic acid ester is 80% by mole or more, preferably 90% by mole (most preferably 100% by mole).

In addition, the above resin component comprises additional monomer units having different functions in addition to the above unit (a1) to satisfy resolution properties, anti-dry-etching properties, and the shape of fine patterns. For examples, these structural units may be of the following combination.

Examples include a structural unit derived from a (meth) acrylic ester having a lactone unit (hereinafter, referred to as (a2) or unit (a2)); a structural unit derived from a (meth) acrylic ester having a polycyclic group that contains an alcoholic hydroxyl group or a cyano group (hereinafter, referred to as (a3) or unit (a3)); and a structural unit containing a polycyclic group, which is different from any of the acid dissociable, dissolution inhibiting group of the unit (a1), the lactone unit of the unit (a2), and polycyclic group which contains the alcoholic hydroxyl group or cyano group-containing (hereinafter, referred to as (a4) or (a4)).

The (a2), (a3), and/or (a4) may be suitably combined with each other depending on the desired characteristics or the like. Preferably, the resin may contain (a1) together with at least one unit selected from the group consisting of (a2), (a3), and (a4) to improve both the resolution properties and the shape of resist patterns. In addition, two or more different units of each unit of (a1) to (a4) may be used in combination.

Furthermore, a structural unit derived from the (meth)acrylic acid ester and a structural unit derived from acrylic acid ester are preferably used such that 10 to 85% by mole, preferably 20 to 80% by mole of the structural unit derived from the (meth)acrylic acid ester is mixed with 15 to 90% by mole, preferably 20 to 80% by mole of the structural unit derived from acrylic acid ester with respect to the total moles of the structural unit derived from the (meth)acrylic acid ester and the structural unit derived from acrylic acid ester.

Next, the above (a1) to (a4) units will be described in detail.

The (a1) unit is a structural unit derived from (meth)acrylic ester having a acid dissociable, dissolution inhibiting group. The acid dissociable, dissolution inhibiting group of the (a1) unit, which can be used, is not particularly limited as far as it has alkaline-dissolution preventing properties, which makes the whole resin component insoluble in alkaline before exposure to light, and dissociates from each other by action of an acid generated after exposure to light to make the whole resin component soluble in alkaline. In general, those widely known in the art include: a group that forms a cyclic or chain tertiary alkyl ester; a carboxyl group of (meth)acrylic acid with a tertiary alkoxy carbonyl group; or a chain alkoxy alkyl group.

The acid dissociable, dissolution inhibiting group of the above (a1) may preferably be a acid dissociable, dissolution inhibiting group, which contains an aliphatic polycyclic group. Examples of the polycyclic group include groups each obtained by removing one hydrogen atom from bicycloalkane, tricycloalkane, or tetracycloalkane, which may be substituted with a fluorine atom or a fluorinated alkyl group or may not be substituted therewith. Specifically, the exemplary groups include those obtained by removing one hydrogen atom from polycycloalkane such as adamantane, norbornane, isobornane, tricyclodecane, or tetracyclododecane. Such a polycyclic group may be appropriately selected from many proposed groups which can be used in ArF resist. Among them, an adamanthyl group, a norbornyl group, and a tetracyclododecanyl group are commercially preferable.

Monomer units suitable for the above (a1) will be represented by the general formulae (1) to (7) below. In general formulae (1) to (7), R is a hydrogen atom or a methyl group, R₁ is a lower alkyl group, each of R₂ and R₃ independently represents a lower alkyl group, R₄ is a tertiary alkyl group, R₅ is a methyl group, and R₆ is a lower alkyl group.

Each of the above R₁ to R₃ and R₆ is preferably a lower linear or branched chain alkyl group having 1 to 5 carbon atoms, such as a methyl group, an ethyl group, a propyl group, an isopropyl group, a n-butyl group, an isobutyl group, a tert-butyl group, a pentyl group, an isopentyl group, and a neopentyl group. Among them, a methyl group and an ethyl group are commercially preferable.

Furthermore, R₄ is a tertiary alkyl group such as a tert-butyl group and a tert-amyl group. The tert-butyl group is commercially preferable.

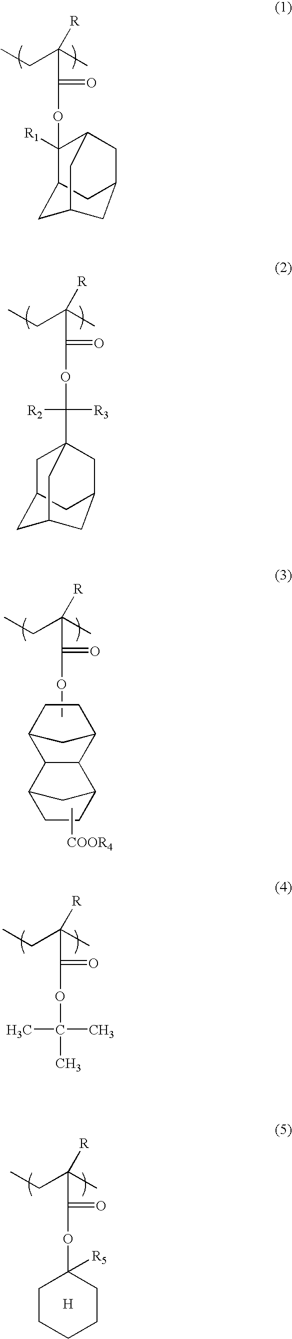

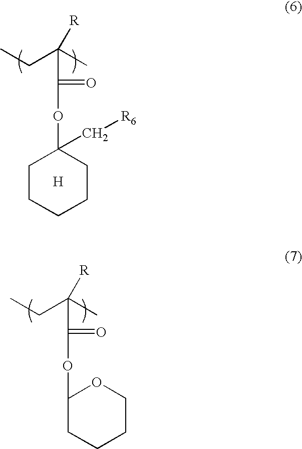

Among those listed above as the (a1) unit, in particular, the structural units represented by the general formulae (1), (2), and (3) are preferable because they are capable of forming patterns having high transparency, high resolution properties, and excellent anti-dry-etching properties.

The above (a2) unit has a lactone unit, so that it can be effective for increasing the hydrophilicity of a developing solution.

Such an (a2) unit may be one having a lactone unit, and may be capable of copolymerizing with any of their structural unit of the resin component.

For instance, examples of the monocyclic lactone unit include a group obtained by removing one hydrogen atom from γ-butyrolactone unit. In addition, examples of the polycyclic lactone unit include a group obtained by removing one hydrogen atom from lactone-containing polycycloalkane.

Favorable monomer units as the above (a2) will be represented by the general formulae (8) to (10) below. In these general formulae, R is a hydrogen atom or a methyl group.

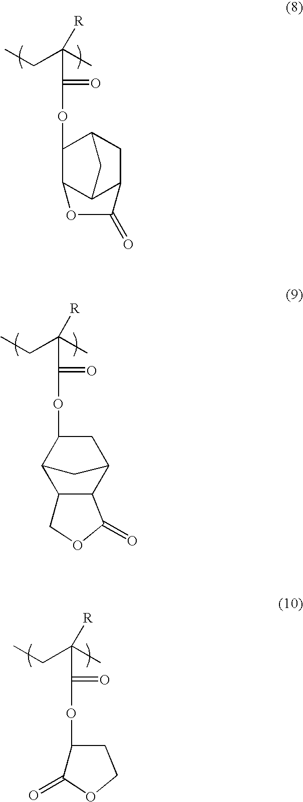

A γ-butyrolactone ester of (meth) acrylic acid having an ester linkage on the α-carbon as shown in the above general formula (10) and norbornane lactone esters as shown in the general formulae (8) and (9) are particularly commercially available and preferable.

The abovementioned (a3) unit is a structural unit which can be derived from (meth)acrylic ester having a polycyclic group that contains an alcoholic hydroxyl group or a cyano group.

The hydroxyl group in the alcoholic hydroxyl group-containing the polycyclic group or the cyano group is a polar group, so that the use thereof can enhance the hydrophilic properties of the whole resin component to a developing solution, thereby improving alkaline solubility in an exposure portion. Therefore, it is preferable because the resolution properties can be improved when the resin component contains (a3).

Furthermore, the polycyclic group in (a3) may be suitably selected from the same aliphatic polycyclic groups as those exemplified in the description of the above (a1).

Examples of the polycyclic group that contains an alcoholic hydroxyl group or a cyano group in the above (a3), which can be preferably used, include a hydroxyl group-containing adamantyl group and a cyano group-containing adamantyl group but are not particularly limited thereto.

Furthermore, it is preferable that the hydroxyl group-containing adamantyl group is one represented by the general formula (II) below, because of the effect it has on increasing the verticality of a cross sectional shape of the pattern. In this general formula, 1 is an integer of 1 to 3.

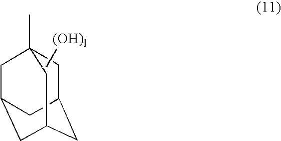

The abovementioned (a3) unit may be one having a polycyclic group that contains an alcoholic hydroxyl group as described above and is capable of copolymerizing with any of other structural units of the resin component.

Concrete examples of the (a3) unit preferably include structural units represented by the general formula (12) described below. Here, in the general formula (12), R is a hydrogen atom or a methyl group.

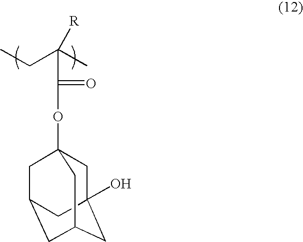

In the above (a4) unit, the polycyclic group being “different from any of the abovementioned acid dissociable, dissolution inhibiting group, the abovementioned lactone unit, and the abovementioned polycyclic group that contains an alcoholic hydroxyl group or a cyano group” means that the polycyclic group of the (a4) unit does not correspond to any of the acid dissociable, dissolution inhibiting group of the (a1) unit, the lactone unit of the (a2) unit, and the polycyclic group that contains an alcoholic hydroxyl group or a cyano group of the (a3) unit. Alternatively, it means that the (a4) unit does not retain any of the acid dissociable, dissolution inhibiting group of the (a1) unit, the lactone unit of the (a2) unit, and the polycyclic group that contains an alcoholic hydroxyl group or a cyano group of the (a3) unit, which constitute the resin component.

The polycyclic group of the above (a4) unit may be selected such that it does not correspond to a structural unit used as any of the above (a1) to (a3) units in one resin component, so that it is not particularly limited. For instance, the polycyclic group of the (a4) unit may be the same aliphatic polycyclic group as one exemplified as the abovementioned (a1) unit. In addition, many conventionally known ArF positive type resist materials can be used.

Particularly, it is preferable that the material is at least one or more selected from a tricyclodecanyl group, an adamantyl group, and a tetracyclododecanyl group, because they are commercially available.

The (a4) unit may be any of those having any of the polycyclic groups described above and which is capable of copolymerizing with any of the other structural units of the resin component.

Preferable examples of the abovementioned (a4) will be represented by the general formulae (13) to (15) described below. In these general formulae, R is a hydrogen atom or a methyl group.

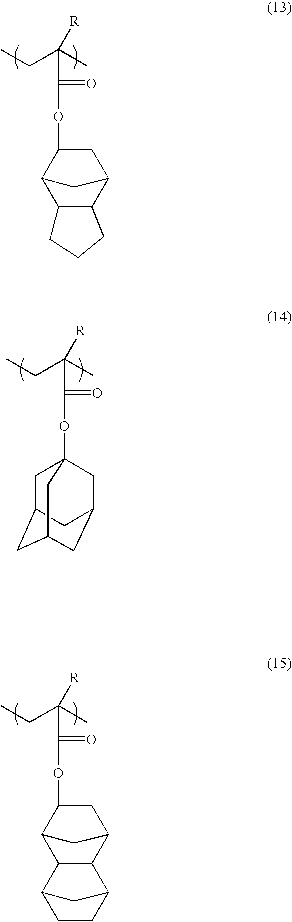

Because of excellent resolution properties, it is preferable that the composition of the above acrylic resin component contains 20 to 60% by mole, preferably 30 to 50% by mole of the (a1) unit with respect to the total of the structural units that constitute the resin component.

In addition, because of excellent resolution, it is preferable that 20 to 60% by mole, preferably 30 to 50% by mole of the (a2) unit is contained with respect to the total structural units that constitute the resin component.

Furthermore, when the (a3) unit is used, because of excellent shape of resist patterns, it is preferable that the 5 to 50% mole, preferably 10 to 40% by mole of the (a3) is contained with respect to the total structural units that constitute the resin component.

When the (a4) unit is used, because of excellent resolution properties from isolated patterns to semi-densified patterns, it is preferable that the 1 to 30% mole, preferably 5 to 20% by mole of the (a4) is contained with respect to the total structural units that constitute the resin component.

The (a1) unit may be suitably combined with at least one unit selected from the (a2), (a3), and (a4) units for any purpose. A three-component polymer of the (a1) unit with the (a2) and (a3) units is preferable because of being excellent in shape of resist patterns, degree of excess-exposure, heat resistance, and resolution. In this case, the contents of the respective structural units (a1) to (a3) are as follows: preferably, the content of the (a1) unit is 20 to 60% by mole, the content of the (a2) unit is 20 to 60% by mole, and the content of the (a3) unit is 5 to 50% by mole.

Furthermore, the mass average molecular weight of the resin component (hereinafter, referred to as polystyrene conversion) is, but not particularly limited to, the range of 5,000 to 30,000, more preferably in the range of 8,000 to 20,000. If it exceeds this range, the solubility of the resin component to a resist solvent becomes worse. If it is smaller than the range, the anti-dry-etching properties or the shape of resist pattern cross section may become worse.

Furthermore, the abovementioned cycloolefin resin is preferably a resin obtained by copolymerizing a structural unit (a5) represented by the general formula (16) described below with a structural unit optionally obtained from the above (a1).

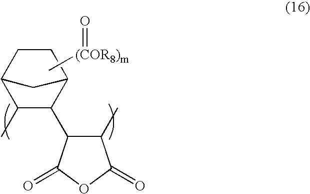

(in which R₈ is a substituent exemplified as a acid dissociable, dissolution inhibiting group in the above (a1) unit, and m is an integer of 0 to 3)

Here, if m is zero (0) in the above (a5) unit, it is preferable to use a copolymer having the (a1) unit.

Furthermore, examples of the above silsesquioxane resin include a structural unit (a6) represented by the following general formula (17) and a structural unit (a7) represented by the following general formula (18).

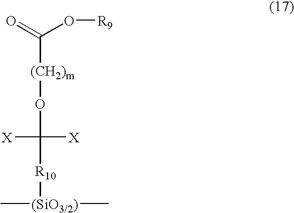

□ in which □₉ is a acid dissociable, dissolution inhibiting group comprised of a hydrocarbon group having an aliphatic monocyclic or polycyclic group, R₁₀ is a linear, branched, or cyclic saturated aliphatic hydrocarbon group, X is an alkyl group having 1 to 8 carbon atoms in which at least one hydrogen atom is substituted with a fluorine atom, and m is an integer of 1 to 3).

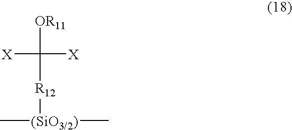

(in which R₁₁ is a hydrogen atom, or a linear, branched, or cyclic alkyl group, R₁₂ is a linear, branched, or cyclic saturated aliphatic hydrocarbon group, and X is an alkyl group having 1 to 8 carbon atoms in which at least one hydrogen atom is substituted with a fluorine atom).

In the abovementioned (a6) and (a7), the acid dissociable, dissolution inhibiting group of R₉ is a group having alkaline-dissolution preventing properties that make the whole silsesquioxane resin alkaline-insoluble, while it is dissociated by the action of an acid generated from an acid-generating agent after exposure to light, thereby making the whole silsesquioxane resin alkaline-soluble.

Such a group may be any of those represented by the chemical formulae (19) to (23) described below, such as a bulky acid dissociable, dissolution inhibiting group comprised of a hydrocarbon group having an aliphatic monocyclic or polycyclic group. The use of such a acid dissociable, dissolution inhibiting group prevents degasification as the dissolution-preventing group is hardly gasified after dissociation.

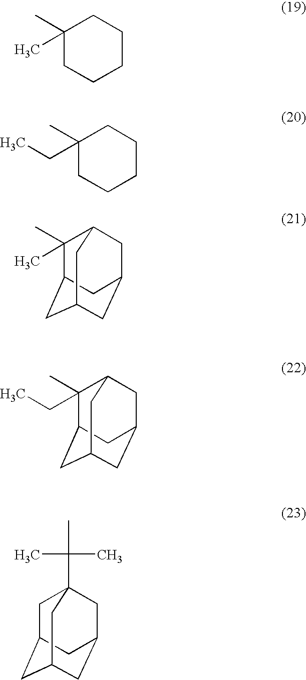

The number of carbon atoms in the above R₉ is preferably 7 to 15, more preferably 9 to 13, because of the difficulty of gasification when dissociated, as well as appropriate dissolubility to a resist solvent and appropriate dissolubility to a developing solution.

The acid dissociable, dissolution inhibiting group, which can be used, may be suitably selected from many proposed resins for resist compositions depending on an optical source used, such as an ArF Excimer laser, as long as the acid dissociable, dissolution inhibiting group is comprised of a hydrocarbon group having an aliphatic monocyclic or polycyclic group. In general, one that forms a cyclic tertiary alkyl ester with the carboxyl group of an (meth) acrylic acid and is widely known in the art.

In particular, it is preferable that an acid dissociable, dissolution inhibiting group contains an aliphatic polycyclic group. The aliphatic polycyclic group may be suitably selected from many of those proposed in the ArF resist. Examples of the aliphatic polycyclic group include those obtained by removing one hydrogen atom from bicycloalkane, tricycloalkane, tetracycloalkane, or the like. More specifically, examples of the aliphatic polycyclic group include those obtained by removing one hydrogen atom from adamantane, norbornane, isobornane, tricyclodecane, tetracyclododecane, or the like.

Among the abovementioned general formulae, a silsesquioxane resin having a 2-methyl adamantyl group represented by the chemical formula (21) and/or a 2-ethyl adamantyl group represented by the chemical formula (22) is preferable because of the difficulty in degasification, while having excellent resist characteristics such as resolution properties and heat resistance.

Furthermore, the number of carbon atoms in each of the above R₁₀ and R₁₂ is preferably in the range of 1 to 20, more preferably in the range of 5 to 12 in terms of dissolubility to a resist solvent and molecular-size control. Particularly, a cyclic, saturated aliphatic hydrocarbon group is preferable because of its advantageous properties, such as the transparency of the resulting silsesquioxane resin to high-energy light, a high glass transition point (Tg), and easiness in control of acid generation from an acid-generating agent at PEB (heating after exposure to light).

The cyclic, saturated aliphatic hydrocarbon group may be a monocyclic group or a polycyclic group. Examples of the polycyclic group include those obtained by removing two hydrogen atoms from bicycloalkane, tricycloalkane, tetracycloalkane, or the like. More specifically, examples of the polycyclic group include those obtained by removing two hydrogen atoms from polycycloalkanes such as adamantane, norbornane, isobornane, tricyclodecane, and tetracyclododecane.

More specifically, examples of the R₁₀ and R₁₂ are groups obtained by removing two hydrogen atoms from aliphatic compounds represented by the chemical formulae (24) to (29) described below or derivatives thereof.

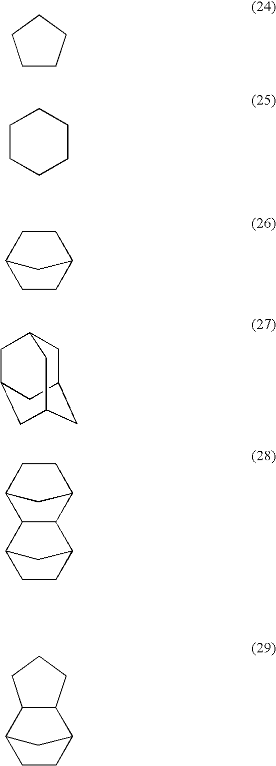

In the aliphatic compounds of the above chemical formulae (24) to (29), the derivatives mean those obtained by substituting at least one hydrogen atom with any of groups including lower alkyl groups such as a methyl group and an ethyl group and halogen atoms such as an oxygen atom, a fluorine atom, a chlorine atom, a bromine atom. Among them, a group obtained by removing two hydrogen atoms from an aliphatic compound selected from the group consisting of the chemical formulae (24) to (29) is preferable in that it has high transparency and is commercially available.

Furthermore, the above R₁₁ is a lower alkyl group having preferably 1 to 10 carbon atoms, more preferably 1 to 4 carbon atoms in terms of dissolubility to a resist solvent. More specifically, examples of the above R₁₁ include a methyl group, an ethyl group, a propyl group, an isopropyl group, a n-butyl group, a sec-butyl group, a tert-butyl group, a cyclopentyl group, a cyclohexyl group, a 2-ethylhexyl group, and a n-octyl group.

R₁₁ is suitably selected from the above candidates depending on the desired alkaline dissolubility of the silsesquioxane resin. The alkaline dissolubility becomes highest when the R₁₁ is a hydrogen atom. In other words, there is an advantage in that an increase in alkaline dissolubility leads to an increase in sensitivity.

On the other hand, the greater the number of carbon atoms in the above alkyl group, and the bulkier the above alkyl group becomes, the more the alkaline dissolubility of the silsesquioxane resin decreases. A decrease in alkaline dissolubility leads to an increase in resistance to an alkaline developing solution, so that an exposure margin at the time of forming resist patterns using the silsesquioxane resin can be improved while lowering size variations due to exposure. In addition, uneven development disappears, so that the roughness of the edged portions of formed resist patterns can be improved.

In the above general formulae (17) and (18), in particular, x is preferably a linear alkyl group. The alkyl group is a lower alkyl group having 1 to 8 carbon atoms, preferably 1 to 4 carbon atoms, in terms of glass transition (Tg) point of the silsesquioxane resin or dissolubility to a resist solvent. Preferably, the more the number of hydrogen atoms to be substituted with fluorine atoms increases, the more the transparency to high energy light or an electron beam of 200 nm or less improves. A perfluoroalkyl group in which all of the hydrogen atoms are substituted with fluorine groups is most preferable. X may be identical with each other or may be different from each other. Here, m in the general formula (17) is an integer of 1 to 3, preferably 1 because of tendency to dissociate a acid dissociable, dissolution inhibiting group.

More specifically, examples of the silsesquioxane resin include those represented by the general formulae (30) and (31) as described below.

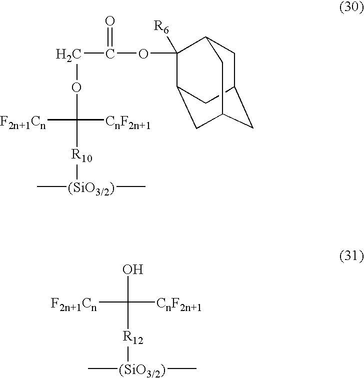

(in which R₆, R₁₀, R₁₂, and n are the same as those described above).

In all of the structural units that constitute the silsesquioxane resin of the present invention, the percentage of the structural unit represented by each of (a6) and (a7) is in the range of 30 to 100% by mole, preferably 70 to 100% by mole, more preferably 100% by mole.

In addition, the percentage of the structural unit represented by (a6) is preferably in the range of 5 to 70% by mole, more preferably 10 to 40% by mole with respect to the total of the structural units represented by (a6) and (a7). The percentage of the structural unit represented by (a7) is preferably in the range of 30 to 95% by mole, more preferably 60 to 90% by mole.

By defining the percentage of the structural unit represented by (a6) within the above range, the percentage of the acid dissociable, dissolution inhibiting group can be directly defined. A change in alkaline dissolubility before and after exposing the silsesquioxane resin to light is suitable for a base resin of a positive type resist composition.

The silsesquioxane resin may have an additional structural unit other than those represented by (a6) and (a7) as long as it does not impair the effects of the present invention. For instance, it may be one used in a silsesquioxane resin for a resist composition of ArF Excimer laser, such as an alkyl silsesquioxane unit having any of alkyl groups including a methyl group, an ethyl group, a propyl group, and a butyl group.

The mass average molecular weight (Mw) of the silsesquioxane resin (polystyrene conversion with gel permeation chromatography) is, but not particularly limited to, preferably in the range of 2,000 to 15,000, more preferably 3,000 to 8,000. If it exceeds this range, the solubility of the resin component to a resist solvent becomes worse. If it is smaller than that range, the shape of resist pattern cross section tends to become worse.

Furthermore, the ratio of mass average molecular weight (Mw) to number average molecular weight (Mn) is, but not particularly limited to, preferably in the range of 1.0 to 6.0, more preferably 1.5 to 2.5. If it exceeds this range, the resolution and the shape of patterns tend to become worse.

In addition, the silsesquioxane resin of the present invention is a polymer having a basic backbone, silsesquioxane, which is constructed of structural units represented by (a6) and (a7). Thus, it has a high transparency to high energy light or an electron beam at 200 nm or less. Therefore, the positive type resist composition containing the silsesquioxane resin of the present invention is useful in, for example, lithography using a light source at a wavelength shorter than that of an ArF Excimer laser and is capable of forming fine resist patterns of 150 nm or less, or 120 nm or less in line width even in a monolayer process. In addition, using as an upper layer of a two-layered resist laminate, it is also useful in process of forming fine resist patterns of 120 nm or less, or 100 nm or less.

Hereafter, various kinds of fluorine-containing polymers are proposed as resist components for F₂ positive type resist. Any polymer among them may be used, although not particularly limited. In particular, a fluorine-containing polymer (a8) comprising an alkaline-soluble structural unit (a8-1) containing an aliphatic ring group having both (i) a fluorine atom or a fluorinated alkyl group and (ii) an alcoholic hydroxyl group is preferable, in which the polymer (a8) has alkaline solubility that varies depending on the action of acid.

The term “alkaline solubility, which varies depending on the action of the acid” of the polymer (a8), means the change in the polymer in an exposure region. An increase in alkaline solubility in the exposure region makes the exposure region alkaline-soluble, so that it can be used as positive type resist. In contrast, a decrease in alkaline solubility in the exposure region makes the exposure region alkaline-insoluble, so that it can be used as negative type resist.

The term “alkaline-soluble structural unit (a8-1) containing an aliphatic ring group together with (i) a fluorine atom or a fluorinated alkyl group and (ii) an alcoholic hydroxyl group” may be one having an aliphatic ring group in a structural unit of the polymer, which is bound to an organic group having both the abovementioned (i) and (ii).

Examples of the aliphatic ring group include those obtained by removing one or more hydrogen atoms from a monocyclic or a polycyclic hydrocarbon, such as cyclopentane, cyclohexane, bicycloalkane, tricycloalkane, and tetracycloalkane.

More specifically, examples of the polycyclic hydrocarbon include those obtained by removing one or more hydrogen atoms from polycyclic alkane, such as adamantane, norbornane, isobornane, tricyclodecane, and tetracyclododecane.

Among them, a group that can be induced by removing a hydrogen atom from cyclopentane, cyclohexane, norbornane, or the like, is commercially preferable.

The above fluorine atom or fluorinated alkyl group may be a fluorine atom or any of those in which part or all of hydrogen atoms of a lower alkyl group is substituted with a fluorine atom. In particular, examples thereof include a trifluoromethyl group, a pentafluoroethyl group, a heptafluoropropyl group, and nonafluorobutyl group. Among them, a fluorine atom and a trifluoromethyl group are commercially preferable.

The alcoholic hydroxyl group (ii) may be just a hydroxyl group or may be an alkyloxy group, alkyloxy alkyl group, or an alkyl group containing an alcoholic hydroxyl group. The alkyloxy group, the alkyloxy alkyl group, or the alkyl group may be a lower alkyloxy group, a lower alkyloxy lower alkyl group, or a lower alkyl group.

The lower alkyloxy groups include, concretely, a methyloxy group, an ethyloxy group, a propyloxy group, and a butyloxy group. The lower alkyloxy lower alkyl groups include, concretely, a methyloxymethyl group, an ethyloxymethyl group, a propyloxymethyl group, and a butyloxymethyl group. The lower alkyl groups include, concretely, a methyl group, an ethyl group, a propyl group, and a butyl group.

As for the above (ii), part or all of hydrogen atoms of an alkyl group, an alkyloxy group, an alkyloxyalkyl group, or an alkyl group in an alkyloxy group containing an alcoholic hydroxyl group, an alkyloxyalkyl group containing an alcoholic hydroxyl group, or an alkyl group containing an alcoholic hydroxyl group may be substituted with fluorine atoms.

The par of hydrogen atoms of an alkyloxy portion of each of the above alkyloxy group containing an alcoholic hydroxyl group or the alkyloxyalkyl group containing an alcoholic hydroxyl group may be preferably substituted with a fluorine atom. In addition, the part of hydrogen atoms of the alkyl group of the alcoholic hydroxyl group-containing alkyl group may be preferably substituted with a fluorine atom. That is, the fluoroalkyloxy group contains an alcoholic hydroxyl group, a fluoroalkyloxyalkyl group contains an alcoholic hydroxyl group, or a fluoroalkyl group contains an alcoholic hydroxyl group.

Examples of the fluoroalkyloxy group containing an alcoholic hydroxyl group include a (HO)C(CF₃)₂CH₂O-group (2-bis (hexafluoromethyl)-2-hydroxy-ethyloxy group) and a (HO)C(CF₃)₂CH₂CH₂O-group (3-bis(hexafluoromethyl)-3-hydroxy-propyloxy group). Examples of the fluoroalkyloxyalkyl group containing an alcoholic hydroxyl group include a (HO)C(CF₃)₂CH₂O—CH₂-group and a (HO)C(CF₃)₂CH₂CH₂O—CH₂-group. Examples of the fluoroalkyl group containing an alcoholic hydroxyl group include a (HO)C(CF₃)₂CH₂-group (2-bis (hexafluoromethyl)-2-hydroxy-ethyl group) and a (HO)C(CF₃)₂CH₂CH₂-group (3-bis(hexafluoromethyl)-3-hydroxy-propyl group).

The groups (i) and (ii) may be directly bound to the aliphatic ring groups, respectively. In particular, the (a8-1) structural unit is preferably a unit represented by the general formula (32) described below, which is formed by binding the fluoroalkyloxy group containing an alcoholic hydroxyl group, the fluoroalkyl oxyalkyl group containing an alcoholic hydroxyl group or the fluoroalkyl group containing an alcoholic hydroxyl group, to a norbornene ring, then opening a double bound of the norbornene ring because they are excellent in transparency, alkaline solubility, and anti-dry-etching properties and are commercially available.

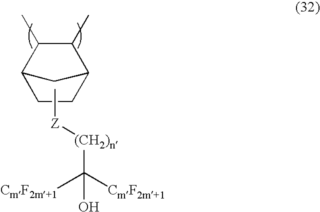

(in which z is an oxygen atom, an oxymethylene group (—O(CH₂)—), or a single bond, and each of n′ and m′ is independently an integer of 1 to 5).

Furthermore, a polymer unit used in combination with such an (a8-1) unit is not particularly limited as far as it is any of those known in the art. When it is used as a polymer that allows an increase in alkaline solubility by the action of a positive-type acid, the structural unit (a1) derived from (meth)acryl ester having the abovementioned acid dissociable, dissolution inhibiting group is preferable because of being excellent in resolution properties.

Such a structural unit (a1) derived from tertiary alkyl ester of (meth) acrylic acid such as tert-butyl (meth) acrylate and tert-amyl (meth)acrylate is preferable.

Furthermore, the polymer (a8) may be a polymer (a9), which contains a fluorine alkylene structural unit (a8-2) for improving the transparency of the polymer. The polymer (a8) contains such a structural unit (a8-2), so that the transparency can be further improved. A preferable structural unit (a8-2) is a unit derived from tetrafluoroethylene.

Hereinafter, the polymer (a8) and the polymer (a9) are represented by the general formulae (33) and (34), respectively.

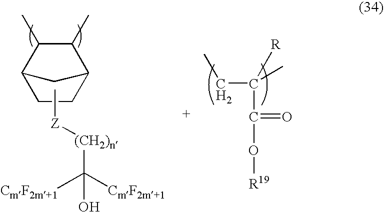

(in which Z, n′, and m′ are the same as those of the general formula (32), R is a hydrogen atom or a methyl group, and R¹⁹ is a acid dissociable, dissolution inhibiting group).

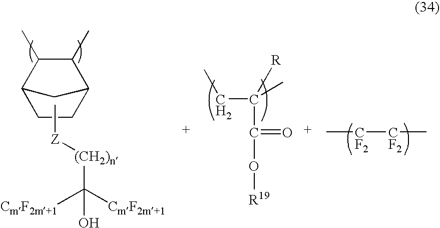

□ in which Z, n′, m′, R and R¹⁹ are the same as those of the general formula (33)).

Furthermore, it may be a polymer which is different from the above polymers (a8) and (a9) and which contains another structural unit (a8-1) as described above, while having an alkaline-solubility which can be varied with the action of acid. The polymer may have the following structural unit.

That is, in the structural unit (a8-1), (i) a fluorine atom or a fluorinated alkyl group and (ii) an alcoholic group are respectively bound to an aliphatic cycle and the cyclic group then constitutes a main chain.

Examples of (i) the fluorine atom or the fluorinated alkyl group include the same as those described above. In addition, (ii) the alcoholic hydroxyl group may be just a hydroxyl group.

The polymer (a10) having such a unit can be prepared by a cyclic polymerization reaction of a diene compound having a hydroxyl group and a fluorine atom. A preferable diene compound is heptadiene because it tends to form a five- or six-membered ring polymer which is excellent in transparency and anti-dry-etching properties. Furthermore, a polymer formed by a cyclic polymerization reaction of 1,1,2,3,3-pentafluoro-4-trifluoromethyl-4-hydroxy-1,6-heptadiene (CF₂═CFCF₂C(CF₃) (OH)CH₂CH═CH₂) is commercially preferable.

When the polymer (a11), which allows an increase in alkaline solubility by action of a positive-type acid, is used, preferable is a polymer containing a structural unit (a8-3), where a hydrogen atom of an alcoholic hydroxyl group is substituted with a acid dissociable, dissolution inhibiting group. The acid dissociable, dissolution inhibiting group is preferably a linear, branched, or circular alkyloxylmethyl group having 1 to 15 carbon atoms in terms of dissolubility of the acid. In particular, a lower alkoxymethyl group such as a methoxymethyl group is preferable because of being excellent in resolution properties and pattern form. Here, the content of the acid dissociable, dissolution inhibiting group is in the range of 10 to 40%, preferably 15 to 30% with respect to the whole hydroxyl groups, because it is capable of forming excellent patterns.

Hereinafter, the polymer (all) represented by the general formula (35) will be shown below.

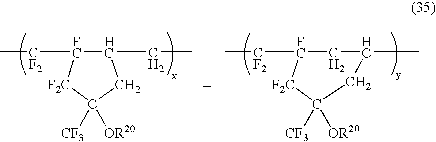

(in which R²⁰ is a hydrogen atom or an alkyloxymethyl group having 1 to 15 carbon atoms, and x and y are 10 to 50% by mole, respectively).

The polymers (a8), (a9), (a10), and (a11) can be prepared by any of the methods described in non-patent documents known in the art, such as S. Kodama et al., “Synthesis of Novel Fluoropolymer for 157 nm Photoresists by Cyclo-polymerization” Proceedings of SPIE, Vol. 4690, (2002) pp 76-83 and patent documents, International Publication No. WO 00/67072, International Publication No. WO 02/65212, and International Publication No. WO 02/64648, respectively.

In addition, the mass average molecular weights of resin components (a8), (a9), (a10), and (a11) (by GPC, polystyrene conversion) is preferably in the range of 5,000 to 80,000, and more preferably 8,000 to 50,000, but not particularly limited to such a range.

Furthermore, the polymer (a8) may be comprised of one or two or more kinds of resins. For example, it may be comprised of a mixture of two or more kinds selected from the group consisting of (a8), (a9), (a10), and (a11) described above or may be used in combination with any of other conventionally-known resins for photoresist composition.

In the case of a resist using a fluorine-containing polymer, it may be principally used as a resist for exposure with a F₂ Excimer laser.

Furthermore, concrete examples of the resin component to be used in the above negative type resist composition preferably include those described below but are not particularly limited as long as it has been conventionally used.

Such a resin component is preferably a resin (a12) having alkaline-insoluble properties with acid and contains two functional groups, which can form esters in molecule by reacting with each other. The resin is imparted with alkaline insolubility such that the functional groups form ester by dehydration with the action of acid generated by an acid-generating agent concurrently added to resist materials. The term “two functional groups which can form ester by reacting with each other” means, for example, a hydroxyl group and a carboxylic or carbonic aid ester for forming a carboxylic acid ester. Such a resin may preferably contain a hydroxyalkyl group and at least one of a carboxyl group and a carboxylic acid ester on a side chain of the resin main backbone.

Furthermore, the resin component may be also preferably a resin component (a13) comprised of a polymer having dicarboxylic acid monoester unit.

In other words, the above (a12) is a resin component having at least a structural unit represented by the general formula (36) described below.

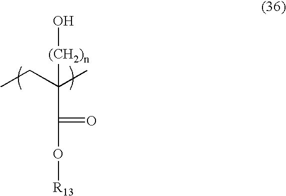

(in which R₁₃ is hydrogen atom, an alkyl group having 1 to 6 carbon atoms, or an alkyl group having a polycyclic ring backbone, such as a norbornyl group, an adamantyl group, a tetracyclododecyl group, or a tricyclodesyl group, and n is an integer of 1 to 5).

Examples of such a resin include a polymer (homopolymer or copolymer) (a12-1) of at least one selected from α-(hydroxyalkyl)acrylic acid and α-(hydroxyalkyl)acrylic acid alkyl ester; and a copolymer (a12-2) of at least one monomer selected from α-(hydroxyalkyl)acrylic acid and α-(hydroxyalkyl)acrylic acid alkyl ester and at least one monomer selected from any other ethylenic unsaturated carboxylic acid and ethylenic unsaturated carboxylic acid ester.

The above polymer (a12-1) may be preferably a copolymer of α-(hydroxyalkyl)acrylic acid and α-(hydroxyalkyl)acrylic acid alkyl ester. In addition, the copolymer (a12-2) may be preferably prepared using at least one selected from the group consisting of: acrylic acid, methacrylic acid, acryl acid alkyl ester, and methacrylic acid alkyl ester as the ethylenic unsaturated carboxylic acid or ethylenic unsaturated carboxylic acid ester.

Examples of hydroxyalkyl groups in α-(hydroxyalkyl)acrylic acid and α-(hydroxyalkyl)acrylic acid alkyl ester as described above include lower hydroxyalkyl groups such as a hydroxymethyl group, a hydroxyethyl group, a hydroxypropyl group, and a hydroxybutyl group. Among them, the hydroxyethyl group and the hydroxymethyl group are preferred from the ease of forming ester.

In addition, examples of an alkyl group on the alkyl ester portion of the α-(hydroxyalkyl)acrylic acid alkyl ester include: lower alkyl groups such as a methyl group, an ethyl group, a propyl group, an isopropyl group, a n-butyl group, a sec-butyl group, a tert-butyl group, and an amyl group; and bridging-type polycyclic hydrocarbon groups such as a bicyclo[2, 2, 1]heptyl group, a norbornyl group, an adamantyl group, a tetracyclo[4, 4, 0, 1^{2.5}, 1^{7.10}]dodecyl group, and tricyclo[5, 2, 1, 0^{2.6}]decyl group. When the alkyl group on the ester portion is a polycyclic hydrocarbon group, it is effective to enhance the anti-dry-etching properties. Among these alkyl groups, particularly, a lower alkyl group such as a methyl group, an ethyl group, a propyl group, and a butyl group are preferable because they are cheap and easily obtainable and thus used as an alcohol component for the formation of ester.

In case of a lower alkyl ester, esterification with a hydroxyalkyl group may occur in a manner similar to the carboxyl group. However, esterification hardly occurs in case of a bridging-type polycyclic hydrocarbon. Therefore, for introducing the ester with the bridging-type polycyclic hydrocarbon into the resin, it is preferable that the resin has a carboxyl group on the side chain thereof.

On the other hand, examples of other ethylenic unsaturated carboxylic acid or ethylenic unsaturated carboxylic acid ester in the above (a12-2) include: unsaturated carboxylic acids such as an acrylic acid, a methacrylic acid, a maleic acid, and a fumaric acid; and alkyl esters, such as methyl, ethyl, propyl, isopropyl, n-butyl, isobutyl, n-hexyl, and octylester, of these unsaturated carboxylic acids. Examples of the alkyl group of the ester portion include acrylic acid esters or methacrylic acid esters having bridging-type polycyclic hydrocarbon groups such as a bicyclo[2, 2, 1]heptyl group, a bornyl group, an adamantyl group, a tetracyclo[4, 4, 0, 1^{2.5}, 1^{7.10}]dodecyl group, and tricyclo[5, 2, 1, 0^{2.6}]decyl group. Among them, acrylic acid and methacrylic acid or lower alkyl esters such as methyl, ethyl, propyl, and n-butyl ester thereof are preferable because of being cheap and easily obtainable.

In the resin of the resin component (a12-2), the ratio of at least one monomer unit selected from α-(hydroxyalkyl)acrylic acid and α-(hydroxyalkyl)acrylic acid alkyl ester to at least one monomer unit selected from any of other ethylenic unsaturated carboxylic acids and ethylenic unsaturated carboxylic acid esters is a mole ratio in the range of 20:80 to 95:5, particularly in the range of 50:50 to 90:10. If the ratio of both units is in the above range, it will be easy to form ester between or within molecules and good resist patterns can be thus obtained.

In addition, the resin component (a13) is a resin component having at least a structural unit represented by the general formula (37) or (38) described below.

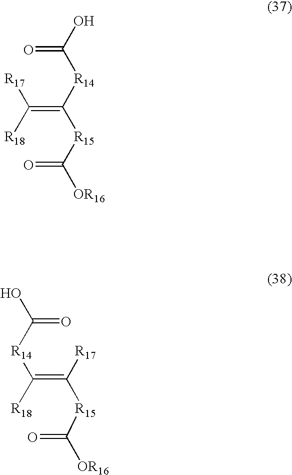

(in which R₁₄ and R₁₅ represent an alkyl group having 0 to 8 carbon atoms, R₁₆ represents a substituent group having at least 2 or more aliphatic structure, and R₁₇ and R₁₈ represent an hydrogen atom or an alkyl group having 1 to 8 carbon atoms).

A negative type resist composition using such a resin composition having a dicarboxylic acid monoester monomer unit is preferable in that it has high resolution properties and reduced line-edge roughness. In addition, it shows a high resistance to swelling, so that it is preferable in a liquid immersion lithography process.

Examples of such a dicarboxylic acid monoester compound include fumaric acid, itaconic acid, mesaconic acid, glutaconic acid, and trumatic acid.

Furthermore, examples of the resin having the abovementioned dicarboxylic acid monoester unit preferably include: a polymer or a copolymer (a13-1) of dicarboxylic acid monoester monomers; and a copolymer (a13-2) of the carboxylic acid monoester monomer with at least one monomer selected from the group consisting of: α-(hydroxyalkyl)acrylic acid, α-(hydroxyalkyl)acrylic acid alkyl ester, and any other ethylenic unsaturated carboxylic acids and ethylenic unsaturated carboxylic acid esters as described above.

The resin component to be used for the above-mentioned negative type resist may be used independently or may be used in combinations of two or more. In addition, the resin composition has a mass average molecular weight of 1,000 to 50,000, preferably 2,000 to 30,000.

Furthermore, an acid-generating agent to be used in combination with a resin component for the above positive or negative type resist may be any agent suitably selected from those conventionally known as acid-generating agents for chemically-amplified resist.

Concrete examples of the acid-generating agent include: onium salts such as diphenyliodonium trifluoromethane sulfonate, (4-methoxyphenyl)phenyliodonium trifluoromethane sulfonate, bis(p-tert-butylphenyl)iodonium trifluoromethane sulfonate, triphenylsulfonium trifluoromethane sulfonate, (4-methoxyphenyl)diphenylsulfonium trifluoromethane sulfonate, (4-methylphenyl)diphenylsulfonium nonafluorobutane sulfonate, (p-tert-butylphenyl)diphenylsulfonium trifluoromethane sulfonate, diphenyliodonium nonafluorobutane sulfonate, bis(p-tert-butylphenyl)iodonium nonafluorobutane sulfonate, triphenylsulfonium nonafluorobutane sulfonate, (4-trifluoromethylphenyl)diphenylsulfonium trifluoromethane sulfonate, (4-trifluoromethylphenyl)diphenylsulfonium nonafluorobutane sulfonate, and tri(p-tert-butylphenyl)sulfonium trifluoromethane sulfonate.

Among onium salts, triphenylsulfonium salts are preferably used because of difficulty in decomposition and generation of organic gas. The amount of the triphenylsulfonium salt added is preferably in the range of 50 to 100% by mole, more preferably 70 to 100% by mole, most preferably 100% by mole with respect to the total amount of the acid-generating agent.

In addition, among triphenylsulfonium salts, triphenylsulfonium salt having perfluoroalkyl sulfonate ions as anions, which is represented by the general formula (39) described below, is preferably used because of its high sensitivity.

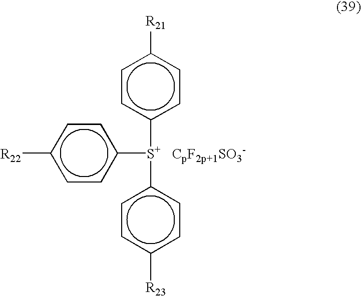

(in which R₂₁, R₂₂, and R₂₃ independently represent an hydrogen atom, a lower alkyl group having 1 to 8, preferably 1 to 4 carbon atoms, or a halogen atom such as chlorine, fluorine, or bromine; p is an integer of 1 to 12, preferably 1 to 8, more preferably 1 to 4).

The acid-generating agents described above may be used independently or may be used in combinations of two or more. The amount of the acid-generating agent added may be 0.5 to 30 parts by mass, preferably 1 to 10 parts with respect to 100 parts by mass of the above resin component. If it is less than 0.5 parts by mass, the formation of patterns is insufficient. On the other hand, if it exceeds 30 parts by mass, a uniform solution is difficult to obtain and thus it may cause a decrease in preservation stability.

Furthermore, the positive or negative type resist composition of the present invention is produced by dissolving any of components described later together with the above resin component and an acid-generating agent into preferably an organic solvent.

The organic solvent may be any of those that dissolve both the resin component and the acid-generating agent and make a solution uniform. Thus, one or more of any conventional solvents for chemically-amplified resist may be suitably selected and used.

The organic solvents may include: ketones such as acetone, methyl ethyl ketone, cyclohexanone, methyl isoamyl ketone, 2-heptanone; polyvalent alcohols and derivatives thereof, such as ethylene glycol, ethylene glycol monoacetate, diethylene glycol, diethylene glycol monoacetate, propylene glycol, propylene glycol monoacetate, dipropylene glycol or monomethyl ether of dipropylene glycol monoacetate, monoethyl ether, monopropyl ether, monobutyl ether, and monophenyl ether; cyclic ethers such as dioxane; and esters such as methyl lactate, ethyl lactate, methyl acetate, ethyl acetate, butyl acetate, methyl pyruvate, ethyl pyruvate, methoxy methyl propionate, and ethoxy ethyl propanoate. These organic solvents may be used independently or as a mixture solvent of two or more solvents.

The positive or negative type resist may contain any amines conventionally known in the art, preferably secondary lower aliphatic amines, tertiary lower aliphatic amines, and organic acids such as organic carboxylic acids, and phosphorous oxo acid, for improving the shape of resist patterns and temporal stabilities, or as a quencher.

The lower aliphatic amines refer to alkyl or alkyl alcohol amines having 5 or less carbon atoms. Examples of the secondary and tertiary amines include trimethylamine, diethylamine, triethylamine, di-n-propylamine, tri-n-propylamine, tribenthylamine, diethanolamine, and triethanolamine. Among these, in particular, an alkanolamine such as triethanol amine is preferable. They may be used independently or in combinations of two or more.

These amines may be typically used in the range of 0.01 to 5.0% by mass with respect to the above resin component.

Preferred examples of the organic carboxylic acid include, for example, malonic acid, citric acid, malic acid, succinic acid, benzoic acid, and salicylic acid.

Examples of phosphorous oxo acid or a derivative thereof include: phosphoric acids and ester derivatives thereof, such as phosphoric acid, phosphoric acid di-n-butylester, and phosphoric acid diphenylester; phosphonic acids and ester derivatives thereof, such as phosphonic acid, phosphonic acid dimethylester, phosphonic acid-di-n-butylester, phenyl phosphonate, phosphonic acid diphenylester, and phosphonic acid dibenzylester; phosphinic acids and ester derivatives thereof, such as phosphinic acid and phenyl phosphinate. Among these, in particular, phosphonic acid is particularly preferable.

The organic acid used is in the range of 0.01 to 5.0 parts by mass per 100 parts by mass of the resin composition. Each of them may be used independently or in combinations of two or more.

These organic acids may be used at an amount in the range of an equivalent mole or less to the amount of the amine.

The positive type resist composition of the present invention may further contain additional additives with miscibility if desired. The additives include, for example, an additional resin for improving the characteristics of a resist film; a surfactant for improving coating abilities, a dissolution-preventing agent, a plasticizer, a stabilizer, a colorant, and a halation inhibitor.

Furthermore, the negative type resist composition of the present invention may be added with a cross-linking agent if required for the purpose of improving the density of cross-linking, and also improving the shape and resolution properties of a resist pattern, and anti-dry-etching properties of resist patterns.

A given cross-linking agent may be suitably selected from those conventionally known in the art, which have been used in negative type resists of conventional chemical amplification. Examples of the cross-linking agent include: aliphatic cyclic hydrocarbons or oxygen-containing derivatives thereof having a hydroxyl group or a hydroxyalkyl group or both of them, such as 2,3-dihydroxy-5-hydroxymethyl norbornane, 2-hydroxy-5,6-bis(hydroxymethyl)norbornane, cyclohexane dimethanol, 3,4,8 (or, 9)-trihydroxy tricyclodecane, 2-methyl-2-adamantanol, 1,4-dioxane-2,3-diol, and 1,3,5-trihydroxycyclohexane; and compounds prepared by reacting any of amino-containing organic compounds such as melamine, acetoguanamine, benzoguanamine, urea, ethylene urea, and glycol uryl with formaldehyde or with both formaldehyde and lower alcohol, and then substituting a hydrogen atom of the amino group with a hydroxymethyl group or a lower alkoxymethyl group, specifically the compounds including hexamethoxymethyl melamine, bis-methoxy-methylurea, bis-methoxymethyl bis-methoxy-ethylene urea, tetramethoxy methyl glycol uryl, and tetra butoxymethyl glycol uryl, but are not particularly limited. In particular, tetrabutoxymethyl glycol uryl is preferable.

These cross-linking agents may be used independently or may be used in combinations of two or more.

Next, a method for forming a resist pattern using a liquid immersion lithography process with the immersion liquid of the present invention will be described.

A first method for forming resist pattern of the present invention is a method for forming a resist pattern using a liquid immersion lithography process. The method comprises the steps of: forming at least a photoresist film on a substrate; directly arranging an immersion liquid comprised of a silicon-based liquid transparent to exposure light, which is used in the exposure process, onto the resist film; selectively exposing the resist film to light through the immersion liquid; optionally heating the resist film; and developing the resist film to form a resist pattern.

In addition, a second method for forming a resist pattern of the present invention is a method for forming a resist pattern. The method comprises the steps of: forming at least a photoresist film on a substrate; forming a protective film on the resist film; directly arranging an immersion liquid comprised of a silicon-based liquid that is used the exposure process and transparent to exposure light, onto the protective film; selectively exposing the resist film to light through the immersion liquid and the protective film; optionally heating the resist film; and developing the resist film to form a resist pattern.

The first method for forming a resist pattern is carries out by at first applying the conventional resist composition on a substrate such as a silicon wafer using a spinner or the like, and then carrying out pre-baking (PAB treatment).

Here, an organic or inorganic antireflection film may be provided between a substrate such as a silicon wafer and a coating film of the resist composition to make a two-layered laminate structure.

The steps previously described may be carried out using well-known procedures. Operation conditions or the like may be suitably determined depending on the composition and characteristics of the resist composition to be used.

Next, a resist film on a substrate is brought into contact with an immersion liquid comprised of a silicon-based liquid transparent to exposure light to be used for liquid immersion lithography. The term “contact” refers to the immersion of a substrate into the immersion liquid or direct arrangement of the immersion liquid on the resist film.

The resist film on the substrate being immersed is exposed to light through a desired mask pattern. In this case, therefore, exposure light reaches to the resist film by passing through the immersion liquid.

At this moment, the resist film directly touches the immersion liquid. However, the immersion liquid is inactive to the resist film as described above, so that no alteration occurs on the resist film, and the resist film itself is also left as it is. Thus, there is no variation in optical properties such as the refractive index. In addition, the resist film has a high refractive index, so that high resolution properties can be attained while preventing a decrease in focal depth, such as in cases involving the use of an optical source with a shorter wavelength, or even high NA lens. Consequently, it is useful in forming a fine pattern.

The wavelength used in exposure is not particularly limited. Any radiation, such as an ArF Excimer laser, KrF Excimer laser, F₂ laser, EUV (extreme ultraviolet), VUV (vacuum ultraviolet radiation), electron ray, X-ray, and soft X ray, can be used. The immersion liquid of the present invention is transparent to light at these wavelengths, so that the wavelength of light used can be mainly determined by characteristics of the resist film.

When the exposure step in immersion with the immersion liquid is completed, for example, the substrate is taken out of the immersion liquid or the immersion liquid is removed from the substrate by means of drying at room temperature, spin drying, heat drying, nitrogen blowing, or the like. The immersion liquid has a boiling point of up to 200° C., so that it can be completely removed from the resist film by any of these treatments.

Next, the resist film exposed to light is subjected to PEB (heating after exposure to light) and then subjected to a developing treatment using an alkaline developing solution made of an alkaline aqueous solution. Post-baking may be carried out subsequently after the developing treatment. After that, preferably, the substrate is rinsed with pure water. This water rinsing may be carried out such that, for example, water is dropped or atomized on the surface of the substrate while rotating the substrate to wash out the developing solution and the resist composition dissolved in the developing solution on the substrate. Subsequently, the substrate is dried to obtain a resist pattern in which the resist film is then subjected to patterning with a mask pattern into a predetermined shape depending on the mask pattern.

The second method for forming a resist pattern is carried out in the same manner as that of the first method for forming a resist pattern, except that a protective film is formed between a resist film and an immersion liquid.

The immersion liquid of the present invention is useful as a means for extending versatility to the liquid immersion lithography process against a resist using a resin having a low resistance to water immersion. However, the immersion liquid of the present invention can be preferably used in a process having such a protective film on the resist film. An application liquid for forming a protective film on the resist film may be preferably an aqueous solution containing a water-soluble or alkaline-soluble film-forming component.

The aqueous film-forming component is not particularly limited as long as it retains water-solubility or alkaline solubility, in addition to transparency to irradiation light. The aqueous film-forming component used is preferably one having the characteristic features of: (i) a uniform coating film that can be formed by any conventional means for coating, such as a spin-coating method; (ii) having no deterioration layer formed between the photoresist film and the aqueous film-forming component, even if the component is applied on the photoresist film; (iii) being sufficiently penetrated by an active light beam; and (iv) being able to form a coating film having a small absorption coefficient and a high transparency.

Examples of such an aqueous film-forming component include: cellulose polymers such as hydroxypropyl methylcellulose phthalate, hydroxypropyl methylcellulose acetate phthalate, hydroxypropyl methylcellulose acetate succinate, hydroxypropyl methylcellulose hexahydrophthalate, hydroxypropyl methylcellulose, hydroxypropyl cellulose, hydroxyethyl cellulose, cellulose acetate hexahydrophthalate, carboxymethyl cellulose, ethylcellulose, and methylcellulose; acrylic acid polymers in which N,N-dimethylacrylamide, N,N-dimethylaminopropyl methacrylamide, N,N-dimethylaminopropyl acrylamide, N-methylacrylamide, diacetone acrylamide, N,N-dimethylaminoethyl methacrylate, N,N-diethylaminoethyl methacrylate, N,N-dimethylaminoethyl acrylate, acryloyl morpholine, acrylic acid, and the like are used as monomers; and vinyl polymers such as polyvinyl alcohol and polyvinyl pyrrolidone. Among these, the acrylic acid polymer, polyvinyl pyrroridone, or the like, which is an aqueous polymer having no hydroxyl group in molecule, is preferable. These aqueous film-forming components may be independently used or may be used in combinations of two or more of them.

In addition, examples of the alkaline-soluble film-forming component include: novolac resins obtained by condensation reactions of phenols (e.g., phenol, m-cresol, xylenol, and trimethyl phenol) with aldehydes (e.g., formaldehyde, formaldehyde precursors, propion aldehyde, 2-hydroxybenzaldehyde, 3-hydroxybenzaldehyde, and 4-hydroxybenzaldehyde) and/or ketones (e.g., methyl ethyl ketone and acetone) in the presence of acidic catalysts; and hydroxystyrene resins such as a hydroxystyrene homopolymer, a copolymer of hydroxystyrene and any of other styrene monomers, and a copolymer of hydroxystyrene with acrylic acid or methacrylic acid or a derivative thereof. These alkaline-soluble film-forming components may be used independently or in combinations of two or more of them.

Comparing the aqueous film-forming component with the alkaline-soluble film-forming component, the aqueous film-forming component is preferable.

The application liquid for forming a protective film may further contain at least one selected from acid-generating agents and acidic compounds. The acid-generating agent may be any known compound used in chemically-amplified resists. Concrete examples of such an acid-generating agent include: onium salts such as diphenyliodonium trifluoromethane sulfonate, (4-methoxyphenyl)phenyliodonium trifluoromethane sulfonate, bis(p-tert-butylphenyl)iodonium trifluoromethane sulfonate, triphenylsulfonium trifluoromethane sulfonate, (4-methoxyphenyl)diphenylsulfonium trifluoromethane sulfonate, (4-methylphenyl)diphenylsulfonium trifluoromethane sulfonate, (4-methylphenyl)diphenylsulfonium nonafluoro butane sulfonate, (p-tert-butylphenyl)diphenylsulfonium trifluoromethane sulfonate, diphenyliodonium nonafluorobutane sulfonate, bis(p-tert-butylphenyl)iodonium nonafluorobutane sulfonate, triphenylsulfonium nonafluorobutane sulfonate, (4-trifluoromethylphenyl)diphenylsulfonium trifluoromethane sulfonate, (4-trifluoromethylphenyl); diphenylsulfonium nonafluorobutane sulfonate, and tri(p-tert-butylphenyl) sulfonium trifluoromethane sulfonate.

Acidic compounds may include inorganic acids such as hydrochloric acid, sulfuric acid, nitric acid, and phosphoric acid and organic acids such as formic acid, acetic acid, propionic acid, benzenesulfonic acid, and toluenesulfonic acid. These organic acid may be independently used or in combinations of two or more of them.

Among the above acidic compounds, preferable acids are aliphatic carboxylic acid or aliphatic sulfonic acid, in which the hydrogen atoms in saturated or unsaturated hydrocarbon groups having 1 to 20 carbon atoms are partially or completely substituted with fluorine atoms, and fluorine-substituted sulfonic compounds.

Here, the above fluorine-substituted carboxylic acid may be perfluoroheptanic acid, perfluorooctanic acid, or the like. In addition, the above fluorine-substituted sulfonic acid may be perfluoropropyl sulfonic acid, perfluorooctyl sulfonic acid, perfluorodecyl sulfonic acid, or the like. More specifically, for example, perfluoroheptanic acid is commercially available in the name of EF-201 or the like and perfluorooctyl sulfonic acid is also commercially available in the name of EF-101 or the like (both manufactured by Tohkem Products, Co., Ltd.). These can both be suitably used.

The above fluorine-substituted sulfonyl compound may be tris(trifluoromethylsulfonyl)methane, bis(trifluoromethylsulfonyl)ammonium, bis(heptafluoro ethylsulfonyl)ammonium, or the like.

The addition of such an acidic compound and/or such an acid-generating agent will lead to an effect of improving the shape of resist patterns and of temporally stabilizing a material for forming a protective film.

The application liquid for forming a protective film is generally used in the form of an aqueous solution and contains an aqueous and alkaline-soluble film-forming component in an amount of preferably 0.5 to 10.0% by mass and the acidic compound and/or the acid-generating agent in an amount of preferably 1.0 to 15.0% by mass. However, the application liquid for forming a protective film is not limited to a specific pH value, but preferably acidic.

The application liquid for forming a protective film may further contain a nitrogen-containing compound. Preferable the nitrogen-containing compounds include a quaternary ammonium hydroxide, an alkanolamine compound, and an amino acid derivative.

The addition of such a nitrogen-containing compound will allow the pH of a material for forming a protective film to be adjusted and attain an effect of improving the shape of resist patterns.

By forming resist patterns in this way, resist patterns having fine line widths, particularly line-and-space patterns having a small pitch can be produced with good resolution. Here, the term “pitch” in line-and-space patterns refers to a total distance of a resist pattern width and a space width in the line width direction of pattern.

### EXAMPLES

Hereinafter, examples of the present invention will be described. However, these examples are only provided for appropriately illustrating the present invention and do not intend to restrict the present invention at all. Here, in the following description, comparative examples will be also described in addition to the examples.

### Example 1

### Evaluation Test 3 for Resist Using Fluorine Polymer

A positive type resist composition 1 was prepared by uniformly dissolving a resin component, an acid-generating agent, and a nitrogen-containing organic compound in an organic solvent described below.

The resin component used was a fluorine polymer represented by the formula described below in an amount of 100 parts by mass. The mass average molecular weight of the fluorine polymer was 25,000; wherein

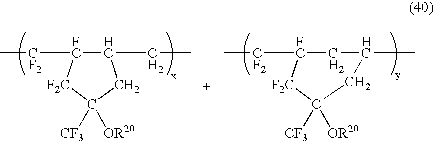

x and y each represent 50%, and R²⁰ represents a hydrogen atom or a methoxymethyl group. A hydrogen atom is 75% and a methoxymethyl group is 25%.

The acid-generating agent used was 2.0 parts by mass of triphenylsulfonium perfluorobutane sulfonate. In addition, the organic solvent used was 1,600 parts by mass of propylene glycol monomethylether acetate (PGMEA). Furthermore, the nitrogen-containing organic compound used was 0.3 parts by mass of triisopropanol amine.

Resist patterns were formed using the positive type resist composition 1 prepared as described above.

At first, an organic antireflection film composition “AR-19” (trade name, Shipley Co., Ltd.) was applied on a silicon wafer by a spin coater and then sintered on a hot plate at 215° C. for 60 seconds until dry, thereby forming an organic antireflection film of 82 nm in thickness. Subsequently, the above positive type resist composition 1 was applied on the antireflection film by a spinner, followed by pre-baking at 95° C. for 90 seconds until dry. Consequently, a resist film of 102 nm in film thickness was formed on the antireflection film.

On the other hand, 500 g of a 20% (M/M) aqueous solution of EF-101 (manufactured by Tohkem Products, Co., Ltd.), perfluorooctyl sulfonic acid (C₈F₁₇SO₃H), was mixed with 80 g of a 20% (M/M) aqueous solution of monoethanol amine. Subsequently, 25 g of a resulting mixture solution was added to 20 g of a 10% (M/M) aqueous solution of polyvinyl pyrrolidone. Then, pure water was added to a resulting aqueous solution to make the total mass 200 g, thereby providing a coating solution for forming a protective film. The coating solution had a pH value of 2.7. The coating solution for forming a protective film was applied on the resist film and then spin-dried. Consequently, a protective film of 35 nm in film thickness was formed.

Hexamethyl disiloxane (trade name “LS7130”, manufactured by Shin-Etsu Silicone Co., Ltd., refractive index n=1.3774, boiling point: 100° C.) was used as an immersion liquid. Here, the refractive index and the attenuation coefficient of hexamethyl disiloxane were measured under N₂ atmosphere and then listed as follows:

| Measurement | Refractive Index | Attenuation |
|---|---|---|
| Wavelength (X) | (n) | Coefficient (k) |
| 156.2 nm | 1.690 | 0.093 |
| 192.8 nm | 1.560 | 0 |
| 246.8 nm | 1.468 | 0 |

The above hexamethyl disiloxane was used as an immersion liquid. A liquid immersion lithographic device used was an experimental device for liquid immersion lithography, manufactured by Nikon Corporation, achieving an “exposure process with two optical-beam interference” comprising the steps of using interference light through a prism instead of exposure light for pattern formation and placing a sample in liquid immersion to expose the sample to the light. The resist film was subjected to liquid immersion lithography at a wavelength of 193 nm (ArF Excimer laser). At this time, the bottom surface of a prism located on the lowermost part of the device had the following layered structure: the hexamethyl disiloxane, the immersion liquid, was provided as an upper layer, and the protective film was provided under the upper layer, and the resist film was further provided under the protective film. In Example 1, a working distance (the distance between the bottom surface of the prism and the resist film) was 150 μm.

After completing the exposure, the substrate was spin-dried and hexamethyl disiloxane, the immersion liquid, was completely removed from the resist film.

Subsequently, the substrate was subjected to a PEB treatment at 115° C. for 90 seconds and then developed in an alkaline developing solution at 23° C. for 60 seconds. The alkaline developing solution used 2.3% by mass of tetramethyl ammonium hydroxide in aqueous solution (trade name “NMD-3”, manufactured by Tokyo Ohka Kogyo Co., Ltd.).

The resist patterns thus obtained with a 65-nm line-and-space of 1:1 were observed under electron scanning microscope (SEM), thereby revealing that good profiles of the patterns were obtained, while no deteriorating phenomena such as fluctuation (partial narrowing of lines) phenomenon was observed. Furthermore, the resulting patterns were observed with respect to the cross-sectional shape of patterns using a convergent ion beam SEM (Altura1235, manufactured by FEI Co., Ltd.). The resulting cross-section was of a good square shape.

### Example 2

### Evaluation Test 3 Using Acryl Polymer

A positive type resist composition 2 was prepared by uniformly dissolving a resin component, an acid-generating agent, and a nitrogen-containing organic compound in an organic solvent described below.

The resin component used was 100 parts by mass of a copolymer of methacrylic acid ether/acrylic acid ester, comprised of three structural components represented by the chemical formulae (41a), (41b), and (41c) described below. The ratio of the respective structural units, p, q, and r, used for preparing the resin component were p=50% by mole, q=30% by mole, and r=20% by mole. The resin component thus prepared had a mass average molecular weight of 10,000.

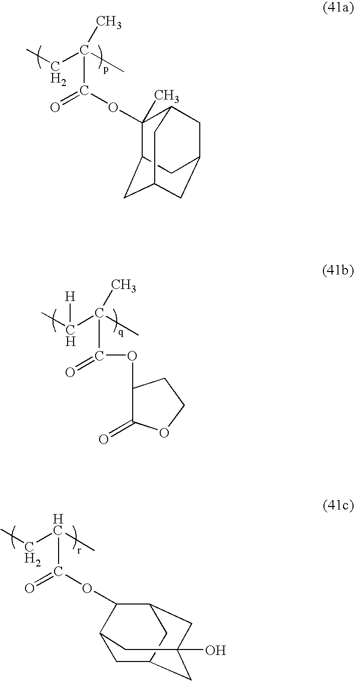

The acid-generating agents used were 3.5 parts by mass of triphenyl sulfonium salt represented by the general formula (42a) described below, and 1.0 parts by mass of triphenyl sulfonium salt represented by the general formula (42b), respectively.

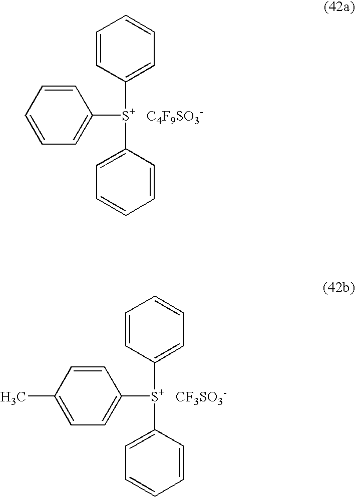

The organic solvent used was 1,600 parts by mass of a mixture solution containing ethyl lactate and PGM in a mass ratio of 6:4. Furthermore, the nitrogen-containing organic compound used was 0.3 parts by mass of triethanol amine.

Resist patterns were formed using the positive type resist composition 2 prepared as described above.

At first, an organic antireflection film composition “AR-19″-(trade name, Shipley Co., Ltd.) was applied on a silicon wafer by a spinner and then sintered on a hot plate at 215° C. for 60 seconds until dry, thereby forming an organic antireflection film of 82 nm in thickness. Subsequently, the above positive type resist composition 2 was applied on the antireflection film by a coater, followed by pre-baking at 125° C. for 90 seconds until dry. Consequently, a resist film of 95 nm in film thickness was formed on the antireflection film.

Subsequently, liquid immersion lithography was carried out in the same manner as that of Example 1 except that the protective film was not used. At this time, the bottom surface of a prism located on the lowermost part of the device had the following layered structure: the hexamethyl disiloxane, the immersion liquid, was provided as an upper layer, and the resist film was further provided under the upper layer. In Example 2, a working distance was 150 μm. After completing the exposure, the substrate was spin-dried and hexamethyl disiloxane, the immersion liquid, was completely removed from the resist film.

Subsequently, the substrate was subjected to a PEB treatment at 115° C. for 90 seconds and then developed in an alkaline developing solution at 23° C. for 60 seconds. The alkaline developing solution used 2.3% by mass of tetramethyl ammonium hydroxide in aqueous solution (trade name “NMD-3”, manufactured by Tokyo Ohka Kogyo Co., Ltd.).

The resist patterns thus obtained with a 65-nm line-and-space of 1:1 were observed under electron scanning microscope (SEM), thereby revealing that good profiles of the patterns were obtained while no deteriorating phenomena such as fluctuation (partial narrowing of lines) phenomenon was observed. Furthermore, the resulting patterns were observed with respect to the cross-sectional shape of patterns using a convergent ion beam SEM (Altura1235, manufactured by FEI Co., Ltd.). The resulting cross-section was of a good square shape.

### Example 3

### Evaluation Test 1 for Resist Using Fluorine Polymer

A positive type resist composition Fl was prepared by uniformly dissolving a resin component, an acid-generating agent, and a nitrogen-containing organic compound in an organic solvent described below. The resin component thus prepared had a mass average molecular weight of 25,000; wherein

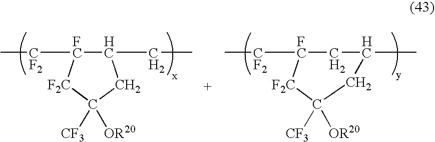

x and y each represent 50%, and R²⁰ represents a hydrogen atom or a methoxymethyl group. A hydrogen atom is 80% and a methoxymethyl group is 20%.

The acid-generating agent used is 5.0 parts by mass of triphenylsulfonium perfluorobutane sulfonate. In addition, the organic solvent used was propylene glycol monomethylether acetate (PGMEA). Furthermore, the nitrogen-containing organic compound used was 0.4 parts by mass of triisopropanol amine and 0.1 parts by mass of salicylic acid. In addition, a dissolution-preventing agent used was 5 parts by mass of a fluorine compound represented by the following chemical formula (44):

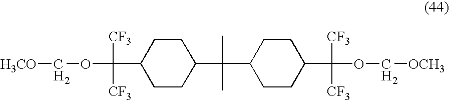

The resist patterns were formed using the positive type resist composition F1 prepared as described above.

At first, an organic antireflection film composition “AR-19” (trade name, Shipley Co., Ltd.) was applied on a silicon wafer by a spin coater and then sintered on a hot plate at 215° C. for 60 seconds until dry, thereby forming an organic antireflection film of 82 nm in thickness. Subsequently, the above positive type resist composition 1 was applied on the antireflection film by a spinner, followed by pre-baking at 90° C. for 90 seconds until dry. Consequently, a resist film of 250 nm in film thickness was formed on the antireflection film.

On the other hand, 500 g of a 20% (M/M) aqueous solution of EF-101 (manufactured by Tohkem Products, Co., Ltd.), perfluorooctyl sulfonic acid (C₈F₁₇SO₃H), was mixed with 80 g of a 20% (M/M) aqueous solution of monoethanol amine. Subsequently, 25 g of a resulting mixture solution was added to 20 g of a 10% (M/M) aqueous solution of polyvinyl pyrrolidone. Then, pure water was added to a resulting aqueous solution to make the total mass 200 g, thereby providing a coating solution for forming a protective film. The coating solution had a pH value of 2.7. The coating solution for forming a protective film was applied on the resist film and then spin-dried (dried by rotation). Consequently, a protective film of 44 nm in film thickness was formed.

Next, patterning light was irradiated (exposed) through mask patterns by an exposure device NSR-S302B (manufactured by Nicon Corp., NA (numerical aperture)=0.60, ⅔ orbicular zone) using ArF Excimer laser (193 nm in wavelength). Then, it was subjected to a PEB treatment at 120° C. for 90 seconds, and then developed for 60 seconds in NMD-3 (alkaline solution made of 2.38% by mass of tetramethyl ammonium in aqueous solution) at 23° C. During the development, the protective film was simultaneously removed.

Resist patterns thus obtained with a 130-nm line-and-space of 1:1 were observed under electron scanning microscope (SEM), thereby revealing that good profiles of the patterns were obtained while no fluctuation or the like was observed.

On the other hand, the formation of resist patterns was carried out as described above except of the follows. In the above pattern formation, while rotating a silicon wafer on which a resist film was formed after exposure, a silicon-based liquid made of hexamethyl disiloxane (trade name “LS7130”, manufactured by Shin-Etsu Silicon Co., Ltd., refractive index n=1.3774, boiling point=100° C.) was sequentially dropped onto the resist film for 1 minute at 23° C. In other words, such a liquid-dropping step was carried out between the exposure and the PEB.

Such a kind of step corresponds to an exposure step in complete immersion in the actual production process, however, on the basis of an analysis previously carried out on a liquid immersion lithography process, it is also theoretically assured that the exposure it self can be completely carried out in an optical system. Therefore, it is simply constructed such that the silicon-based liquid, a refractive index liquid (immersion liquid), is loaded on the resist film after exposure to only evaluate the influence of the immersion liquid on the resist film after previously exposing the resist film to light.

Resist patterns with a 130-nm line-and-space of 1:1 thus obtained were observed under electron scanning microscope (SEM), thereby revealing that good profiles of the patterns were obtained while no fluctuation or the like was observed. The silicon-based solvent made of hexamethyl disiloxane may not have any bad influence on the resist film at all in the immersion process.

### Example 4

### Evaluation Test 2 for Resist Using Fluorine Polymer

One side of a crystal substrate having a diameter of 1 inch was deposited with gold and the substrate was then specifically rotated at about 2,000 rpm while turning the gold-deposited side up. Subsequently, the positive type resist composition F1 used in Example 3 was applied on the gold-deposited surface by a spinner and then dried at 90° C. for 90 seconds to make a film thickness of 150 nm after being dried. The resist was partially exfoliated so that a substrate electrode is brought into contact with a socket electrode, thereby forming a resist-coating film of 150 nm in thickness, which was referred to as a non-exposed coating film.

Next, the above non-exposed coating film was immersed in hexamethyl disiloxane and then subjected to a measurement to determine variations in film thickness of the coating film by a film-thickness gauge “RDA-QZ3” manufactured by Litho Tech Japan Corporation using a quarts crystal microbalance (hereinafter, referred to as QCM) for a maximum time period of 300 seconds for the measurement while being immersed.

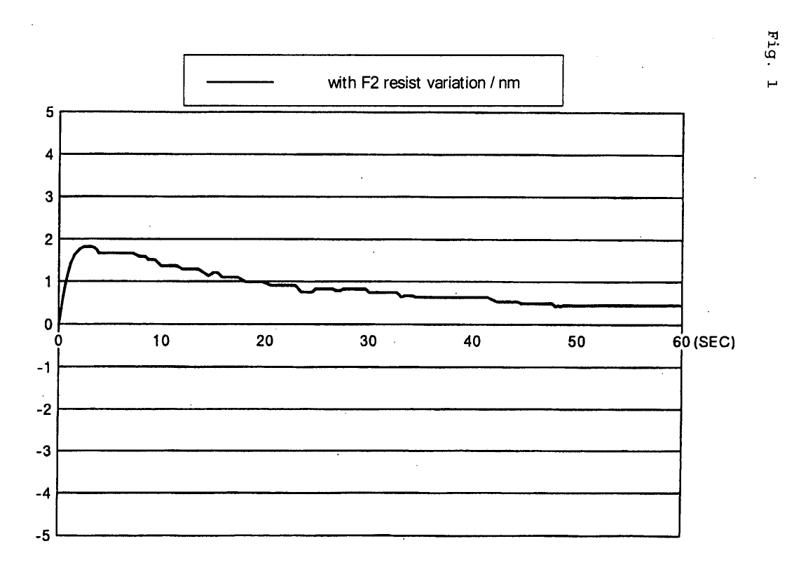

Furthermore, variations in frequencies of the quartz substrate were measured and the resulting data was then processed by the accompanying analytical software, followed by plotting film thickness against immersion time in a graphical representation. The graph of the present experiment was shown in FIG. 1.

Furthermore, for clarifying the difference in variations of film thickness of an unexposed sample, in the graph, an immersion time of zero (0) second was provided as a standard. The difference from the film thickness at that time was written and then plotted on the graph again. Thus, if it is thinner than the initial film thickness, a negative value can be expressed. If it is thicker than the initial film thickness, on the other hand, a positive value can be expressed. Both the maximum in the positive direction and the maximum in the negative direction of variations of film thickness were calculated. If there was no positive or negative behavior, then the value was defined as zero (0) nm. A maximum increase in film thickness within 10 seconds from starting the measurement was 1.87 nm, so that some swelling phenomenon was observed. However, it was confirmed that there was no trouble at all in general use in liquid immersion lithography process. Besides, dissolution phenomenon or the like had not been observed at all.

From the results of Example 4, it has turned out that there is no fear of deteriorating a resist film even if hexamethyl disiloxane is used as an immersion liquid.

### INDUSTRIAL APPLICABILITY

As is evident from the above description, the immersion liquid for a liquid immersion lithography process of the present invention comprises a silicon-based liquid, so that it attains a high refractive index and also attains high resolution properties just as in the case with the use of a shorter-wavelength optical source or high NA lens even an optical source having the same exposure wavelength is employed, as well as no decrease in focal depth width. Therefore, it is advantageous in that the production of high-precision resist patterns with excellent resist-pattern profile configurations. In addition, even if a resist film is constructed using the conventional resist composition, there is no improper phenomenon, for example, roughening of the surface of resist pattern such as T-top formation of the resist pattern, fluctuation of patterns, or stringing phenomenon. Therefore, the immersion liquid of the present invention is suitable for the production of resist patterns.

Furthermore, from the results of Examples 1 to 4, it becomes evident that the immersion liquid for a liquid immersion lithography process of the present invention has advantageous features of (1) having sufficient transparency to exposure light; (2) chemically inactive to a resist film and a protective film thereon and no deterioration occurred in the shape of resist patterns during the formation thereof; and (3) no adverse affect of, for example, a decrease in refractive index required for attaining high resolution properties of an immersion liquid, due to leakage of components of a resist film or protective film into the immersion liquid. With respect to the refractive index, any comparison with conventional immersion liquids, such as water and fluorine-based inert liquids has not been conducted. However, from the mathematical formulae I described above, it is theoretically evident that high resolution properties can be attained as far as the immersion liquid has a physical property known as a high refractive index.

Furthermore, a method for forming a resist pattern using the immersion liquid for a liquid immersion lithography process of the present invention is advantageous in that, even if the immersion liquid is arranged on a resist film, or even if a protective film is formed on the resist film and the immersion liquid of the present invention is then arranged on the protective film, excellent resist patterns can be produced.

1. An immersion liquid to be used for a liquid immersion lithography process in which a resist film is exposed to light through a liquid, comprising:
a silicon-based liquid transparent to exposure light to be used in the liquid immersion lithography process.

2. The immersion liquid according to claim 1, wherein
the liquid immersion lithography process exposes the resist film to light through the immersion liquid having a predetermined thickness and a refractive index higher than air, which is arranged on at least the resist film in a pathway allowing exposure light for lithography to reach the resist film.

3. The immersion liquid according to claim 1, wherein
the refractive index of the silicon-based liquid is at least 0.01 higher than the refractive index of water.

4. The immersion liquid according to claim 1, wherein
the silicon-based liquid is an organic siloxane represented by the following formula: 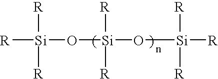
wherein R represents an organic group and n represents an integer of 0 or more.

5. The immersion liquid according to claim 1, wherein
a base polymer of a resist composition that forms the resist film is a polymer comprising a (meth)acrylic ester unit.

6. The immersion liquid according to claim 1, wherein
a base polymer of a resist composition that forms the resist film is a fluorine-containing polymer.

7. The immersion liquid according to claim 6, wherein
the base polymer includes an alkaline-soluble structural unit containing an aliphatic ring group having both:
(i) one selected from the group consisting of a fluorine atom and a fluorinated alkyl group, and
(ii) an alcoholic hydroxyl group, wherein
alkaline solubility varies depending on acidic action.

8. A method for forming a resist pattern with a liquid immersion lithography process, comprising the steps of:
forming at least a resist film on a substrate;
directly arranging an immersion liquid on the resist film, where the immersion liquid comprises a silicon-based liquid transparent to exposure light, which is used in the liquid immersion lithography process;
selectively exposing the resist film to light through the immersion liquid; and
forming a resist pattern by developing the resist film.

9. A method for forming a resist pattern with a liquid immersion lithography process, comprising the steps of:
forming at least a resist film on a substrate;
forming a protective film on the resist film;
directly arranging an immersion liquid on the protective film, where the immersion liquid comprises a silicon-based liquid transparent to exposure light, which is used in the liquid immersion lithography process;
selectively exposing the resist film to light through the immersion liquid and the protective film; and
forming a resist pattern by developing the resist film.

10. The method according to claim 9, further comprising the step of subjecting the resist film to a heat treatment after the exposure step.

11. The method according to claim 9, wherein
the liquid immersion lithography process exposes the resist film to light through the immersion liquid having a predetermined thickness and a refractive index higher than air, which is arranged on at least a resist film in a pathway allowing exposure light for lithography to reach the resist film.

12. The method according to claim 9, wherein
the refractive index of the silicon-based liquid is at least 0.01 higher than the refractive index of water.

13. The method according to claim 9, wherein
the silicon-based liquid is an organic siloxane represented by the following formula: 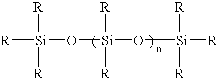
wherein R represents an organic group and n represents an integer of 0 or more.

14. The method according to claim 9, wherein
a base polymer of a resist composition that forms the resist film is a polymer comprising a (meth)acrylic ester unit.

15. The method according to claim 9, wherein
a base polymer of a resist composition that forms the resist film is a fluorine-containing polymer.

16. The method according to claim 9, wherein
a base polymer of a resist composition that forms the resist film includes an alkaline-soluble structural unit (a1) containing an aliphatic ring group having both:
(i) one selected from the group consisting of a fluorine atom and a fluorinated alkyl group, and
(ii) an alcoholic hydroxyl group, wherein
alkaline solubility varies depending on acidic action.

17. The method for forming the resist pattern according to claim 8, further comprising the step of subjecting the resist film to a heat treatment after the exposure step.

18. The method according to claim 8, wherein the liquid immersion lithography process exposes the resist film to light through the immersion liquid having a predetermined thickness and a refractive index higher than air, which is arranged on at least a resist film in a pathway allowing exposure light for lithography to reach the resist film.

19. The method according to claim 8, wherein the refractive index of the silicon-based liquid is at least 0.01 higher than the refractive index of water.

20. The method according to claim 8, wherein the silicon-based liquid is an organic siloxane represented by the following formula: 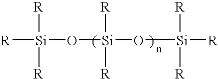
wherein R represents an organic group and n represents an integer of 0 or more.

21. The method according to claim 8, wherein a base polymer of a resist composition that forms the resist film is a polymer comprising a (meth)acrylic ester unit.

22. The method according to claim 8, wherein a base polymer of a resist composition that forms the resist film is a fluorine-containing polymer.

23. The method according to claim 8, wherein a base polymer of a resist composition that forms the resist film includes an alkaline-soluble structural unit (a1) containing an aliphatic ring group having both:
(i) one selected from the group consisting of a fluorine atom and a fluorinated alkyl group, and
(ii) an alcoholic hydroxyl group, wherein
alkaline solubility varies depending on acidic action.
